(19) United States
(12) Patent Application Publication
(10) Pub. No.: US 2008/0220610 A1
(43) Pub. Date: Sep. 11, 2008

(54) Silicon oxide polishing method utilizing colloidal silica

(75) Inventors: Benjamin Bayer, Ashland, VA (US); Zhan Chen, Aurora, IL (US); Jeffrey P. Chamberlain, Aurora, IL (US); Robert Vacassy, Aurora, IL (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(73) Assignee: Cabot Microelectronics Corporation, Aurora, IL (US)

(21) Appl. No.: 11/478,004

(22) Filed: Jun. 29, 2006

(51) Int. Cl. H01L 21/306

(52) U.S. Cl. 438/693; 257/E21.23

(57) ABSTRACT

The inventive method comprises chemically-mechanically polishing a substrate with a polishing composition comprising a liquid carrier and sol-gel colloidal silica abrasive particles.

### FIELD OF THE INVENTION

This invention pertains to a method of polishing a silicon oxide substrate.

### BACKGROUND OF THE INVENTION

Integrated circuits are made up of millions of active devices formed in or on a substrate, such as a silicon wafer. The active devices are chemically and physically connected onto a substrate and are interconnected through the use of multilevel interconnects to form functional circuits. Typical multilevel interconnects comprise a first metal layer, an interlevel dielectric layer, and sometimes a third and subsequent metal layers. Interlevel dielectrics, such as doped and undoped silicon dioxide (SiO₂) and/or low-κ dielectrics, are used to electrically isolate the different metal layers.

The electrical connections between different interconnection levels are made through the use of metal vias. U.S. Pat. No. 5,741,626, for example, describes a method for preparing dielectric tantalum nitride (TaN) layers. Moreover, U.S. Pat. No. 4,789,648 describes a method for preparing multiple metallized layers and metallized vias in insulator films. In a similar manner, metal contacts are used to form electrical connections between interconnection levels and devices formed in a well. The metal vias and contacts may be filled with various metals and alloys, such as, for example, titanium (Ti), titanium nitride (TiN), aluminum copper (Al—Cu), aluminum silicon (Al—Si), copper (Cu), tungsten (W), and combinations thereof (hereinafter referred to as “via metals”).

In one semiconductor manufacturing process, metal vias and/or contacts are formed by a blanket metal deposition followed by a chemical-mechanical polishing (CMP) step. In a typical process, via holes are etched through an interlevel dielectric (ILD) to interconnection lines or to a semiconductor substrate. Next, a barrier film is formed over the ILD and is directed into the etched via hole. Then, a via metal is blanket-deposited over the barrier film and into the via hole. Deposition is continued until the via hole is filled with the blanket-deposited metal. Finally, the excess metal is removed by chemical-mechanical polishing (CMP) to form metal vias. Processes for manufacturing and/or CMP of vias are disclosed in U.S. Pat. Nos. 4,671,851, 4,910,155, and 4,944,836.

Compositions, systems, and methods for planarizing or polishing the surface of a substrate, especially for CMP, are well known in the art. Polishing compositions or systems (also known as polishing slurries) typically contain an abrasive material in an aqueous solution and are applied to a surface by contacting the surface with a polishing pad saturated with the polishing composition. When used for polishing substrates comprising metals, the polishing compositions often comprise an oxidizing agent. The purpose of the oxidizing agent is to convert the surface of the metals into a softer, more readily abradable material than the metal itself. Thus, polishing compositions comprising oxidizing agents in conjunction with abrasives generally require less aggressive mechanical abrasion of the substrate, which reduces mechanical damage to the substrate caused by the abrading process. Additionally, the presence of the oxidizing agent frequently increases removal rates for the metals and increases throughput in a production setting.

A CMP system ideally results in a polished planar surface without residual metal films on the polished surface of the ILD, and with all of the vias having metal at heights that are even with the level of the polished surface of the ILD. However, once the high points are quickly polished, the load is shared by lower points which are now within reach of the pad, thereby resulting in a relatively lower polishing pressure. After total removal of the metal layer from the surface of the ILD, the polishing is shared between the metal layer that is level with the ILD surface and the ILD itself. Since the polishing rate of the metal is different from that of the ILD, and, in some cases, greater than that of the ILD, metal is removed from further below the level of the ILD, thus leaving spaces. The formation of these spaces is known in the art as dishing. Severe dishing in large metal active devices is a source of yield loss, especially when it occurs at lower levels of the substrate, where dishing causes trapped metal defects in the above lying layer(s).

In many CMP operations, silicon oxide is utilized as the underlying dielectric material. Typically, silicon oxide-based dielectric films have very low removal rates when polished using a composition having an acidic pH. This limitation prevents non-selective polishing of metals such as tungsten at low pH and can result in dishing.

There is a need in the art for polishing compositions and methods that can provide non-selective polishing of the metal layer relative to the dielectric layer. The invention provides such compositions and methods. These and other advantages of the invention, as well as additional inventive features, will be apparent from the description of the invention provided herein

### BRIEF SUMMARY OF THE INVENTION

The invention provides a method of chemically-mechanically polishing a substrate, which method comprises (i) providing a substrate comprising at least one layer of silicon oxide, (ii) providing a chemical-mechanical polishing composition comprising (a) a liquid carrier, and (b) sol-gel colloidal silica abrasive particles with an average primary particle size of about 20 nm to about 30 nm suspended in the liquid carrier, (iii) contacting the substrate with a polishing pad and the chemical-mechanical polishing composition, (iv) moving the substrate relative to the polishing pad and the chemical-mechanical polishing composition, and (v) abrading at least a portion of the silicon oxide to polish the substrate.

### DETAILED DESCRIPTION OF THE INVENTION

The invention provides a method of chemically-mechanically polishing a substrate. The method comprises (i) providing a substrate comprising at least one layer of silicon oxide, (ii) providing a chemical-mechanical polishing composition, (iii) contacting the substrate with a polishing pad and the chemical-mechanical polishing composition, (iv) moving the substrate relative to the polishing pad and the chemical-mechanical polishing composition, and (v) abrading at least a portion of the silicon oxide to polish the substrate. The polishing composition comprises, consists essentially of, or consists of (a) a liquid carrier, and (b) sol-gel colloidal silica abrasive particles with an average primary particle size of about 20 nm to about 30 nm suspended in the liquid carrier.

The substrate to be polished using the method of the invention can be any suitable substrate which comprises at least one layer of silicon oxide. Suitable substrates include, but are not limited to, flat panel displays, integrated circuits, memory or rigid disks, metals, interlayer dielectric (ILD) devices, semiconductors, micro-electro-mechanical systems, ferroelectrics, and magnetic heads. The silicon oxide can comprise, consist essentially of, or consist of any suitable silicon oxide, many of which are known in the art. Suitable types of silicon oxide include but are not limited to borophosphosilicate glass (BPSG), plasma-enhanced tetraethyl ortho silicate (PETEOS), thermal oxide, undoped silicate glass, and high density plasma (HDP) oxide. Preferably, the substrate also comprises a metal layer. The metal can comprise, consist essentially of, or consist of any suitable metal, many of which are known in the art, such as, for example, tungsten.

The polishing pad can be any suitable polishing pad, many of which are known in the art. Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

The polishing pad can comprise fixed abrasive particles on or within the polishing surface of the polishing pad, or the polishing pad can be substantially free of fixed abrasive particles. Fixed abrasive polishing pads include pads having abrasive particles affixed to the polishing surface of the polishing pad by way of an adhesive, binder, ceramer, resin, or the like or abrasives that have been impregnated within a polishing pad so as to form an integral part of the polishing pad, such as, for example, a fibrous batt impregnated with an abrasive-containing polyurethane dispersion.

The polishing pad can have any suitable configuration. For example, the polishing pad can be circular and, when in use, typically will have a rotational motion about an axis perpendicular to the plane defined by the surface of the pad. The polishing pad can be cylindrical, the surface of which acts as the polishing surface, and, when in use, typically will have a rotational motion about the central axis of the cylinder. The polishing pad can be in the form of an endless belt, which, when in use, typically will have a linear motion with respect to the cutting edge being polished. The polishing pad can have any suitable shape and, when in use, have a reciprocating or orbital motion along a plane or a semicircle. Many other variations will be readily apparent to the skilled artisan.

The polishing composition comprises an abrasive, which desirably is suspended in the liquid carrier (e.g., water). The abrasive typically is in particulate form. In particular, the abrasive comprises, consists essentially of, or consists of sol-gel processed colloidal silica particles, which are commercially available from sources such as Nalco Co. and Fuso Chemical Co. The particles which comprise the abrasive tend to form aggregates, the size of which can be measured using light scattering or disc centrifugation techniques. Aggregate particle size is commonly referred to as the secondary particle size. Primary particle size is defined as the unit building block of the aggregate. The primary particle size is obtainable from the specific surface area as measured by the BET method.

The colloidal silica particles can have an average primary particle size of about 20 nm or more (e.g., about 21 nm or more, about 22 nm or more, about 23 nm or more, or about 24 nm or more). The colloidal silica particles can have an average primary particle size of about 30 nm or less (e.g., about 29 nm or less, about 28 nm or less, about 27 nm or less, or about 26 nm or less). Accordingly, the colloidal silica particles can have an average primary particle size of about 20 nm to about 30 nm (e.g., about 21 nm to about 29 nm, about 22 nm to about 28 nm, about 23 nm to about 27 nm, or about 24 nm to about 26 nm). More preferably, the colloidal silica particles have an average primary particle size of about 25 mm.

Any suitable amount of abrasive can be present in the polishing composition. Typically, about 0.01 wt. % or more (e.g., about 0.05 wt. % or more) abrasive will be present in the polishing composition. More typically, about 0.1 wt. % or more (e.g., about 1 wt. % or more, about 5 wt. % or more, about 7 wt. % or more, about 10 wt. % or more, or about 12 wt. % or more) abrasive will be present in the polishing composition. The amount of abrasive in the polishing composition typically will be about 30 wt. % or less, more typically will be about 20 wt. % or less (e.g., about 15 wt. % or less). Preferably, the amount of abrasive in the polishing composition is about 1 wt. % to about 20 wt. %, and more preferably about 5 wt. % to about 15 wt. % (e.g., about 7 wt. % to about 15 wt. %).

A liquid carrier is used to facilitate the application of the abrasive and any optional additives to the surface of a suitable substrate to be polished (e.g., planarized). The liquid carrier can be any suitable solvent including lower alcohols (e.g., methanol, ethanol, etc.), ethers (e.g., dioxane, tetrahydrofuran, etc.), water, and mixtures thereof. Preferably, the liquid carrier comprises, consists essentially of, or consists of water, more preferably deionized water.

The polishing composition also may comprise an oxidizing agent, which can be any suitable oxidizing agent for one or more materials of the substrate to be polished with the polishing composition. Preferably, the oxidizing agent is selected from the group consisting of bromates, bromites, chlorates, chlorites, hydrogen peroxide, hypochlorites, iodates, monoperoxy sulfate, monoperoxy sulfite, monoperoxyphosphate, monoperoxyhypophosphate, monoperoxypyrophosphate, organo-halo-oxy compounds, periodates, permanganate, peroxyacetic acid, and mixtures thereof. The oxidizing agent can be present in the polishing composition in any suitable amount. Typically, the polishing composition comprises about 0.01 wt. % or more (e.g., about 0.02 wt. % or more, about 0.1 wt. % or more, about 0.5 wt. % or more, or about 1 wt. % or more) oxidizing agent. The polishing composition preferably comprises about 20 wt. % or less (e.g., about 15 wt. % or less, about 10 wt. % or less, or about 5 wt. % or less) oxidizing agent. Preferably, the polishing composition comprises about 0.01 wt. % to about 20 wt. % (e.g., about 0.05 wt. % to about 15 wt. %, about 0.1 wt. % to about 10 wt. %, about 0.3 wt. % to about 6 wt. %, or about 0.5 wt. % to about 4 wt. %) oxidizing agent.

The polishing composition, specifically the liquid carrier with any components dissolved or suspended therein, can have any suitable pH. The actual pH of the polishing composition will depend, in part, on the type of substrate being polished. The polishing composition can have a pH of less than about 7 (e.g., about 6 or less, about 5 or less, about 4 or less, about 3.5 or less, or about 3.3 or less). The polishing composition can have a pH of about 1 or more (e.g., about 2 or more, about 2.1 or more, about 2.2 or more, about 2.3 or more, about 2.5 or more, about 2.7 or more, or about 3 or more). The pH can be, for example, from about 1 to about 6 (e.g., from about 2 to about 5, from about 2 to about 4, from about 2 to about 3.5, from about 2.3 to about 3.5, or from about 2.3 to about 3.3).

The pH of the polishing composition can be achieved and/or maintained by any suitable means. More specifically, the polishing composition can further comprise a pH adjustor, a pH buffering agent, or a combination thereof. The pH adjustor can comprise, consist essentially of, or consist of any suitable pH-adjusting compound. For example, the pH adjustor can be any suitable acid, such as an inorganic or an organic acid, or combination thereof. For example, the acid can be nitric acid. The pH buffering agent can be any suitable buffering agent, for example, phosphates, acetates, borates, sulfonates, carboxylates, ammonium salts, and the like. The polishing composition can comprise any suitable amount of a pH adjustor and/or a pH buffering agent, provided such amount is sufficient to achieve and/or maintain the desired pH of the polishing composition, e.g., within the ranges set forth herein.

The polishing composition optionally comprises a corrosion inhibitor (i.e., a film-forming agent). The corrosion inhibitor can comprise, consist essentially of, or consist of any suitable corrosion inhibitor. Preferably, the corrosion inhibitor is glycine. The amount of corrosion inhibitor used in the polishing composition typically is about 0.0001 wt. % to about 3 wt. % (preferably about 0.001 wt. % to about 2 wt. %) based on the total weight of the polishing composition.

The polishing composition optionally comprises a chelating or complexing agent. The complexing agent is any suitable chemical additive that enhances the removal rate of the substrate layer being removed, or that removes trace metal contaminants in silicon polishing. Suitable chelating or complexing agents can include, for example, carbonyl compounds (e.g., acetylacetonates and the like), simple carboxylates (e.g., acetates, aryl carboxylates, and the like), carboxylates containing one or more hydroxyl groups (e.g., glycolates, lactates, gluconates, gallic acid and salts thereof, and the like), di-, tri-, and poly-carboxylates (e.g., oxalates, oxalic acid, phthalates, citrates, succinates, tartrates, malates, edetates (e.g., dipotassium EDTA), mixtures thereof, and the like), carboxylates containing one or more sulfonic and/or phosphonic groups, and the like. Suitable chelating or complexing agents also can include, for example, di-, tri-, or polyalcohols (e.g., ethylene glycol, pyrocatechol, pyrogallol, tannic acid, and the like), polyphosphonates such as Dequest 2010, Dequest 2060, or Dequest 2000 (available from Solutia Corp.), and amine-containing compounds (e.g., ammonia, amino acids, amino alcohols, di-, tri-, and polyamines, and the like). The choice of chelating or complexing agent will depend on the type of substrate layer being removed.

It will be appreciated that many of the aforementioned compounds can exist in the form of a salt (e.g., a metal salt, an ammonium salt, or the like), an acid, or as a partial salt. For example, citrates include citric acid, as well as mono-, di-, and tri-salts thereof, phthalates include phthalic acid, as well as mono-salts (e.g., potassium hydrogen phthalate) and di-salts thereof; perchlorates include the corresponding acid (i.e., perchloric acid), as well as salts thereof. Furthermore, certain compounds or reagents may perform more than one function. For example, some compounds can function both as a chelating agent and an oxidizing agent (e.g., certain ferric nitrates and the like).

The polishing composition optionally further comprises one or more other additives. Such additives include acrylates comprising one or more acrylic subunits (e.g., vinyl acrylates and styrene acrylates), and polymers, copolymers, and oligomers thereof, and salts thereof.

The polishing composition can comprise a surfactant and/or rheological control agent, including viscosity enhancing agents and coagulants (e.g., polymeric rheological control agents, such as, for example, urethane polymers). Suitable surfactants can include, for example, cationic surfactants, anionic surfactants, nonionic surfactants, amphoteric surfactants, mixtures thereof, and the like. Preferably, the polishing composition comprises a nonionic surfactant. One example of a suitable nonionic surfactant is an ethylenediamine polyoxyethylene surfactant. The amount of surfactant in the polishing composition typically is about 0.0001 wt. % to about 1 wt. % (preferably about 0.001 wt. % to about 0.1 wt. % and more preferably about 0.005 wt. % to about 0.05 wt. %).

The polishing composition can comprise an antifoaming agent. The antifoaming agent can comprise, consist essentially of, or consist of any suitable anti-foaming agent. Suitable antifoaming agents include, but are not limited to, silicon-based and acetylenic diol-based antifoaming agents. The amount of anti-foaming agent in the polishing composition typically is about 10 ppm to about 140 ppm.

The polishing composition can comprise a biocide. The biocide can comprise, consist essentially of, or consist of any suitable biocide, for example an isothiazolinone biocide. The amount of biocide in the polishing composition typically is about 1 to about 50 ppm, preferably about 10 to about 20 ppm.

The polishing composition preferably is colloidally stable. The term colloid refers to the suspension of the particles in the liquid carrier. Colloidal stability refers to the maintenance of that suspension through time. A polishing composition is considered colloidally stable if, when the polishing composition is placed into a 100 ml graduated cylinder and allowed to stand unagitated for a time of 2 hours, the difference between the concentration of particles in the bottom 50 ml of the graduated cylinder ([B] in terms of g/ml) and the concentration of particles in the top 50 ml of the graduated cylinder ([T] in terms of g/ml) divided by the initial concentration of particles in the polishing composition ([C] in terms of g/ml) is less than or equal to 0.5 (i.e., {[B]−[T]}/[C]≦0.5). Preferably, the value of [B]−[T]/[C] is less than or equal to 0.3, more preferably is less than or equal to 0.1, even more preferably is less than or equal to 0.05, and most preferably is less than or equal to 0.01.

The polishing composition can be prepared by any suitable technique, many of which are known to those skilled in the art. The polishing composition can be prepared in a batch or continuous process. Generally, the polishing composition can be prepared by combining the components thereof in any order. The term “component” as used herein includes individual ingredients (e.g., oxidizing agent, abrasive, etc.) as well as any combination of ingredients (e.g., water, halogen anion, surfactants, etc.).

The polishing composition can be supplied as a one-package system comprising a liquid carrier, and optionally an abrasive and/or other additives. Alternatively, some of the components, such as an oxidizing agent, can be supplied in a first container, either in dry form, or as a solution or dispersion in the liquid carrier, and the remaining components, such as the abrasive and other additives, can be supplied in a second container or multiple other containers. Other two-container, or three or more container combinations of the components of the polishing composition are within the knowledge of one of ordinary skill in the art.

Solid components, such as an abrasive, can be placed in one or more containers either in dry form or as a solution in the liquid carrier. Moreover, it is suitable for the components in the first, second, or other containers to have different pH values, or alternatively to have substantially similar, or even equal, pH values. The components of the polishing composition can be partially or entirely supplied separately from each other and can be combined, e.g., by the end-user, shortly before use (e.g., 1 week or less prior to use, 1 day or less prior to use, 1 hour or less prior to use, 10 minutes or less prior to use, or 1 minute or less prior to use).

The polishing composition also can be provided as a concentrate which is intended to be diluted with an appropriate amount of liquid carrier prior to use. In such an embodiment, the polishing composition concentrate can comprise a liquid carrier, and optionally other components in amounts such that, upon dilution of the concentrate with an appropriate amount of liquid carrier, each component will be present in the polishing composition in an amount within the appropriate range recited above for each component. For example, each component can be present in the concentrate in an amount that is about 2 times (e.g., about 3 times, about 4 times, or about 5 times) greater than the concentration recited above for each component in the polishing composition so that, when the concentrate is diluted with an appropriate volume of liquid carrier (e.g., an equal volume of liquid carrier, 2 equal volumes of liquid carrier, 3 equal volumes of liquid carrier, or 4 equal volumes of liquid carrier, respectively), each component will be present in the polishing composition in an amount within the ranges set forth above for each component. Furthermore, as will be understood by those of ordinary skill in the art, the concentrate can contain an appropriate fraction of the liquid carrier present in the final polishing composition in order to ensure that the polyether amine and other suitable additives, such as an abrasive, are at least partially or fully dissolved or suspended in the concentrate.

The inventive method of polishing a substrate is particularly suited for use in conjunction with a chemical-mechanical polishing (CMP) apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention (which generally is disposed between the substrate and the polishing pad), with the polishing pad moving relative to the substrate, so as to abrade at least a portion of the substrate to polish the substrate.

Desirably, the CMP apparatus further comprises an in situ polishing endpoint detection system, many of which are known in the art. Techniques for inspecting and monitoring the polishing process by analyzing light or other radiation reflected from a surface of the workpiece are known in the art. Desirably, the inspection or monitoring of the progress of the polishing process with respect to a substrate being polished enables the determination of the polishing end-point, i.e., the determination of when to terminate the polishing process with respect to a particular substrate. Such methods are described, for example, in U.S. Pat. No. 5,196,353, U.S. Pat. No. 5,433,651, U.S. Pat. No. 5,609,511, U.S. Pat. No. 5,643,046, U.S. Pat. No. 5,658,183, U.S. Pat. No. 5,730,642, U.S. Pat. No. 5,838,447, U.S. Pat. No. 5,872,633, U.S. Pat. No. 5,893,796, U.S. Pat. No. 5,949,927, and U.S. Pat. No. 5,964,643.

Polishing refers to the removal of at least a portion of a surface to polish the surface. Polishing can be performed to provide a surface having reduced surface roughness by removing gouges, crates, pits, and the like, but polishing also can be performed to introduce or restore a surface geometry characterized by an intersection of planar segments.

The method of the invention can be used to polish any suitable substrate comprising at least one layer of silicon oxide. The silicon oxide layer can be removed at a rate of about 500 Å/min or more (e.g., about 600 Å/min or more, about 700 Å/min or more, about 800 Å/min or more, about 900 Å/min or more, or about 1000 Å/min or more). The silicon oxide layer can be removed at a rate of about 4000 Å/min or less (e.g., about 3800 Å/min or less, about 3700 Å/min or less, about 3500 Å/min or less, about 3300 Å/min or less, or about 3000 Å/min or less). Accordingly, the silicon oxide layer can be removed from the substrate at a rate of about 500 Å/min to about 4000 Å/min (e.g., about 600 Å/min to about 3700 Å/min, about 700 Å/min to about 3500 Å/min, about 800 Å/min to about 3300 Å/min, or about 1000 Å/min to about 3000 Å/min).

The substrate can further comprise at least one layer of tungsten. The tungsten layer can be removed at a rate of about 500 Å/min or more (e.g., about 600 Å/min or more, about 700 Å/min or more, about 800 Å/min or more, about 900 Å/min or more, about 1000 Å/min or more, about 1500 Å/min or more, or about 2000 Å/min or more). The tungsten layer can be removed at a rate of about 4000 Å/min or less (e.g., about 3500 Å/min or less, about 3000 Å/min or less, about 2800 Å/min or less, about 2500 Å/min or less, or about 2000 Å/min or less). Accordingly, the tungsten layer can be removed from the substrate at a rate of about 500 Å/min to about 4000 Å/min (e.g., about 600 Å/min to about 3700 Å/min, about 700 Å/min to about 3500 Å/min, about 800 Å/min to about 3300 Å/min, or about 1000 Å/min to about 3000 Å/min).

The following examples further illustrate the invention but, of course, should not be construed as in any way limiting its scope.

### EXAMPLE 1

This example demonstrates the relationship between the size and concentration of sol-gel processed colloidal silica particles present in a polishing composition and the removal rates of silicon oxide and tungsten achieved with such a chemical-mechanical polishing composition.

A PETEOS wafer and a tungsten wafer were polished with nine different compositions. Each of the polishing compositions contained 2 wt. %, 7 wt. %, or 12 wt. % sol-gel processed colloidal silica particles from Nalco Co., 170 ppm malonic acid, 0.02071 wt. % Fe(NO₃)₃.9H₂O, and 1250 ppm TBAH, and was adjusted to a pH of 3.3. The average primary particle size of the sol-gel processed colloidal silica particles of each polishing composition was 7 nm, 25 nm, or 80 nm.

The tungsten removal rate (Å/min) and the PETEOS removal rate (Å/min) were determined for each composition, and the results are shown in Table 1.

TABLE 1

| | | Silica | | | Average |
|---|---|---|---|---|---|
| | Silica | Particle | PETEOS | Tungsten | PETEOS |
| | Particle | Concen- | Removal | Removal | Removal |
| Polishing | Size | tration | Rate | Rate | Rate |
| Composition | (nm) | (wt. %) | (Å/min) | (Å/min) | (Å/min) |
| 1A (comparative) | 7 | 2 | 601.8 | 3867.9 | 638.04 |
| 1B (comparative) | 7 | 7 | 771.1 | 3810.6 | |
| 1C (comparative) | 7 | 12 | 541.2 | 3535.9 | |
| 1D (invention) | 25 | 2 | 598.9 | 3261.6 | 1525.82 |
| 1E (invention) | 25 | 7 | 1618.3 | 4107.8 | |
| 1F (invention) | 25 | 12 | 2360.3 | 4459.5 | |
| 1G (comparative) | 80 | 2 | 632.4 | 4122.0 | 964.13 |
| 1H (comparative) | 80 | 7 | 1040.2 | 3249.4 | |
| 1I (comparative) | 80 | 12 | 1219.8 | 3007.3 | |

The average PETEOS removal rate (Å/min) was calculated by averaging the removal rates for the three different concentrations for each average abrasive primary particle size of the colloidal silica particles. As is apparent from the data presented in Table 1, the silicon oxide removal rate is substantially higher when the colloidal silica particles have a size of about 25 nm as opposed to 7 nm or 80 nm, while maintaining a high rate of tungsten polishing.

The data recited in Table 1 also illustrate the rate of silicon oxide removal (Å/min) relative to the concentration of the colloidal silica particles of the three different compositions. As is apparent from the data recited in Table 1, the silicon oxide removal rate is substantially higher when the colloidal silica particles have a size of about 25 nm and are present at a concentration of greater than about 2 wt. % (e.g., at a concentration of 7-12 wt. %).

### EXAMPLE 2

This example illustrates the relationship between the size of sol-gel processed colloidal silica particles present in a polishing composition and the removal rates of silicon oxide and tungsten achieved with such a chemical-mechanical polishing composition.

A PETEOS wafer and a tungsten wafer were polished with three different compositions. Each of the polishing compositions contained 8 wt. % sol-gel processed colloidal silica particles from Fuso Chemical Co., 93 ppm malonic acid, 0.0723 wt. % Fe(NO₃)₃.9H₂O, and 1250 ppm TBAH, and was adjusted to a pH of 3.3. The average primary particle size of the sol-gel processed colloidal silica particles of each polishing composition was 15 nm, 25 nm, or 35 nm.

The tungsten removal rate (Å/min) and PETEOS removal rate (Å/min) were determined for each composition, and the results are set forth in Table 2.

TABLE 2

| | | | Tungsten |
|---|---|---|---|
| | Silica | PETEOS | Removal |
| Polishing | Particle | Removal | Rate |
| Composition | Size (nm) | Rate (Å/min) | (Å/min) |
| 2A (invention) | 15 | 152.5 | 3361.2 |
| 2B (invention) | 25 | 2989.2 | 3276.8 |
| 2C (invention) | 35 | 2366.4 | 2952.2 |

The data recited in Table 2 illustrate the rate of PETEOS removal (Å/min) relative to the average primary particle size (nm) of the colloidal silica particles of the various compositions. As is apparent from the data recited in Table 2, the silicon oxide removal rate is substantially higher when the colloidal silica particles have an average size of about 25 nm, as opposed to 15 nm or 35 nm, while maintaining a high rate of tungsten polishing. The data recited in Table 2 are similar to the data recited in Table 1 of Example 1, despite the use of sol-gel processed colloidal silica particles from two different manufacturers (i.e., Nalco and Fuso). Considering the differences in starting materials, processing conditions, and final morphologies of the particles from Nalco and Fuso, it is surprising that the 25 nm colloidal silica particles from both manufacturers exhibited silicon oxide removal rates substantially higher than particles of other sizes. Such results indicate the importance of the primary particle size of the colloidal silica particles in increasing the removal rate of silicon oxide.

### EXAMPLE 3

This example illustrates the relationship between the pH of a polishing composition containing sol-gel processed colloidal silica particles with an average size of 25 nm and the removal rate of silicon oxide and tungsten achieved with such a chemical-mechanical polishing composition.

A PETEOS wafer and a tungsten wafer were polished with six different compositions, each of which contained 5 wt. % sol-gel processed colloidal silica particles from Fuso (25 nm average primary particle size), 0.0398 wt. % Fe(NO₃)₃.9H₂O, 500 ppm glycine, and 1000 ppm TBAH. The six different compositions contained three different amounts of malonic acid and were at a pH of either 2.5 or 3.3.

The tungsten removal rate (Å/min) and PETEOS removal rate (Å/min) were determined for each composition and the results are set forth in Table 3.

TABLE 3

| | | Malonic Acid | PETEOS | Tungsten |
|---|---|---|---|---|
| Polishing | | Concentration | Removal | Removal |
| Composition | pH | (ppm) | Rate (Å/min) | Rate (Å/min) |
| 3A (invention) | 2.5 | 85.3 | 1081 | 1182 |
| 3B (invention) | 3.3 | 85.3 | 1856 | 1301 |
| 3C (invention) | 2.5 | 153.6 | 1117 | 1089 |
| 3D (invention) | 3.3 | 153.6 | 2121 | 1260 |
| 3E (invention) | 2.5 | 221.9 | 1288 | 1136 |
| 3F (invention) | 3.3 | 221.9 | 2039 | 1175 |

As is apparent from the data set forth in Table 3, the silicon oxide removal rate is substantially higher when the polishing composition has a pH of 3.3, as opposed to 2.5, while maintaining a high rate of tungsten polishing. This was true for all of the evaluated concentrations of malonic acid.

In addition, a polishing composition containing 5 wt. % sol-gel processed colloidal silica particles from Fuso (25 nm average primary particle size), 0.01664 wt. % Fe(NO₃)₃.9H₂O, 1500 ppm glycine, 250 ppm malonic acid, and 1742.7 ppm K₂SO₄, and having a pH of 2.3, was used to polish a PETEOS wafer and a tungsten wafer. The tungsten removal rate was 3773 Å/min and the PETEOS removal rate was 1351 Å/min.

It should be noted that the iron catalyst contained in the above polishing compositions becomes unstable above a pH of about 4.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A method of chemically-mechanically polishing a substrate, which method comprises:
(i) providing a substrate comprising at least one layer of silicon oxide,
(ii) providing a chemical-mechanical polishing composition comprising:
(a) a liquid carrier, and
(b) sol-gel colloidal silica abrasive particles with an average primary particle size of about 20 nm to about 30 nm suspended in the liquid carrier,
(iii) contacting the substrate with a polishing pad and the chemical-mechanical polishing composition,
(iv) moving the substrate relative to the polishing pad and the chemical-mechanical polishing composition, and
(v) abrading at least a portion of the silicon oxide to polish the substrate.

2. The method of claim 1, wherein the liquid carrier comprises water.

3. The method of claim 1, where the abrasive particles have an average primary particle size of about 20 nm to about 28 nm.

4. The method of claim 1, where the abrasive particles have an average primary particle size of about 25 nm.

5. The method of claim 1, wherein the abrasive particles are present in an amount of about 5 wt. % or more based on the weight of the liquid carrier and any components dissolved or suspended therein.

6. The method of claim 1, wherein the abrasive particles are present in an amount of about 7 wt. % to about 30 wt. % based on the weight of the liquid carrier and any components dissolved or suspended therein.

7. The method of claim 6, wherein the liquid carrier comprises water.

8. The method of claim 7, where the abrasive particles have an average primary particle size of about 20 nm to about 28 nm.

9. The method of claim 8, wherein the liquid carrier with any components dissolved or suspended therein has a pH of about 5 or less.

10. The method of claim 1, wherein the chemical-mechanical polishing composition comprises an oxidizing agent which oxidizes at least a portion of the substrate.

11. The method of claim 1, wherein the liquid carrier with any components dissolved or suspended therein has a pH of less than about 7.

12. The method of claim 1, wherein the liquid carrier with any components dissolved or suspended therein has a pH of about 5 or less.

13. The method of claim 1, wherein the liquid carrier with any components dissolved or suspended therein has a pH of about 4 or less.

14. The method of claim 1, wherein the liquid carrier with any components dissolved or suspended therein has a pH of about 3.5 or less.

15. The method of claim 1, wherein the liquid carrier with any components dissolved or suspended therein has a pH of about 2 to about 3.5.

16. The method of claim 1, wherein the liquid carrier with any components dissolved or suspended therein has a pH of about 2.3 to about 3.3.

17. The method of claim 1, wherein the silicon oxide is removed from the substrate at a rate of about 500 Å/min to about 4000 Å/min.

18. The method of claim 1, wherein the silicon oxide is removed from the substrate at a rate of about 1000 Å/min to about 3000 Å/min.

19. The method of claim 1, wherein the substrate further comprises at least one layer of tungsten.

20. The method of claim 19, wherein the tungsten is removed from the substrate at a rate of about 1000 Å/min to about 3000 Å/min.
